(19) United States
(12) Patent Application Publication
(10) Pub. No.: US 2010/0254108 A1
(43) Pub. Date: Oct. 7, 2010

(54) DISPLAY DEVICE AND METHOD OF DRIVING THE SAME

(75) Inventors: Seong-II KIM, Cheonan-si (KR); Jung-Hoon KU, Seoul (KR); In-Han JEON, Suwon-si (KR); Jun-Ho HWANG, Asan-si (KR); Eun-Jeong KIM, Seoul (KR); Choong-Hwa KIM, Seongnam-si (KR); Ri-Na YOU, Seoul (KR)

Correspondence Address: CANTOR COLBURN, LLP, 20 Church Street, 22nd Floor, Hartford, CT, 06103, US

(73) Assignee: SAMSUNG ELECTRONICS CO., LTD., Suwon-si (KR)

(21) Appl. No.: 12/604,008

(22) Filed: Oct. 22, 2009

(30) Foreign Application Priority Data
Apr. 6, 2009 (KR) 10-2009-0029544

(51) Int. Cl. H05K 7/00; H05K 1/02

(52) U.S. Cl. 361/782; 174/260

(57) ABSTRACT

A display device includes a display panel on which an image is displayed, and a driving board. The driving board includes a substrate, a first multi-layer ceramic condenser disposed on the substrate and to which a first current is supplied, and a second multi-layer ceramic condenser disposed substantially parallel with the first multi-layer ceramic condenser and to which a second current is supplied. The first current and the second current are supplied to the first multi-layer ceramic condenser and the second multi-layer ceramic condenser, respectively, in opposite directions.

This application claims priority to Korean Patent Application No. 10-2009-0029544, filed on Apr. 6, 2009, and all the benefits accruing therefrom under 35 U.S.C. §119, the content of which in its entirety is herein incorporated by reference.

### BACKGROUND OF THE INVENTION

1. Field of the Invention

The present invention relates to a display device and a method of driving the same and, more particularly, to a display device including substantially reduced vibration and noise from multi-layer ceramic condensers included therein, and a method of driving the display device.

2. Description of the Related Art

A liquid crystal display (“LCD”) is a widely used type of flat panel display. Typically, the liquid crystal display includes two panels, such as an upper panel and a lower panel disposed opposite to, e.g., facing, the upper panel. Field generating electrodes, such as pixel electrodes and common electrodes, are disposed on the lower panel and the upper panel, respectively, and a liquid crystal layer is interposed therebetween. During operation of the liquid crystal display, a voltage is supplied to the field generating electrodes to generate an electric field in the liquid crystal layer, and the electric field determines an alignment direction of liquid crystal molecules in the liquid crystal layer. As a result, an image is displayed on the liquid crystal display by controlling an amount of light transmitted through the liquid crystal layer.

More particularly, the liquid crystal display typically includes a common electrode substrate including a common electrode disposed thereon, and a thin film transistor (“TFT”) substrate including a TFT array disposed thereon. The common electrode substrate faces the TFT substrate, and the liquid crystal layer is thereby interposed between the common electrode substrate and the TFT substrate.

The liquid crystal display displays images by applying voltages to a space between the common electrode substrate and the TFT substrate, to rearrange, e.g., to control, the liquid crystal molecules of the liquid crystal layer. Accordingly, the amount of light transmitted through the liquid crystal layer is adjusted, e.g., is controlled.

Liquid crystal displays are generally categorized as non-emissive type displays, e.g., displays which do not inherently emit light. Since non-emissive type displays are not self-emissive, they require a backlight unit, which is typically disposed at a bottom portion of the TFT substrate as a light source for providing light.

In addition, the liquid crystal display generally includes a printed circuit board (“PCB”) including various driving circuits for driving a liquid crystal panel therein. Components and wiring forming the driving circuits are necessarily disposed on the PCB. Accordingly, it is desired to arrange the components and wirings in a space-efficient manner, to reduce manufacturing costs and/or a size of the liquid crystal display, for example.

To efficiently arrange devices in a limited, relatively narrow space, the devices are arranged to minimize distances therebetween. However, as component-to-component distance, component-to-wiring distance and/or wiring-to-wiring distance becomes shorter, electrical interference occurs.

In particular, when a driving voltage is applied, a multi-layer ceramic condenser in the liquid crystal display causes vibration, due to repeated cycles of expansion and shrinkage in a direction along which an electric field is applied, as the multi-layer ceramic condenser undergoes expansion and shrinkage due to a piezo effect. In addition, when the multi-layer ceramic condenser resonates with its adjacent multi-layer ceramic condensers, substantial vibration and/or noise is generated.

### BRIEF SUMMARY OF THE INVENTION

Exemplary embodiments of present invention provide a display device with advantages that include, but are not limited to, substantially reduced vibration and/or noise from multi-layer ceramic condensers.

Exemplary embodiments of the present invention also provide a method of driving a display device including, but not limited to, the above-mentioned advantages.

A display device according to an exemplary embodiment includes a display panel on which an image is displayed, and a driving board. The driving board includes a substrate, a first multi-layer ceramic condenser disposed on the substrate and to which a first current is supplied, and a second multi-layer ceramic condenser disposed substantially in parallel with the first multi-layer ceramic condenser and to which a second current is supplied. The first current and the second current are supplied to the first multi-layer ceramic condenser and the second first multi-layer ceramic condenser, respectively, in opposite directions.

In an exemplary embodiment, a method of driving a driving device includes applying a first current to a first multi-layer ceramic condenser and a second current to a second multi-layer ceramic condenser arranged substantially in parallel to the first multi-layer ceramic condenser on a substrate to output a driving signal, and displaying an image on a display panel using the driving signal. The first current and the second current are supplied to the first multi-layer ceramic condenser and the second multi-layer ceramic condenser, respectively, in opposite directions.

### BRIEF DESCRIPTION OF THE DRAWINGS

The above and other aspects, features and advantages of the present invention will become more readily apparent by describing in further detail exemplary embodiments thereof with reference to the accompanying drawings, in which:

FIG. 1 is a block diagram of an exemplary embodiment of a display device according the present invention;

FIG. 2 is a schematic circuit diagram of a direct current to direct current (“DC-DC”) converter included in the display device shown in FIG. 1;

FIG. 3 is a plan view of a driving board included in the display device shown in FIG. 1;

FIG. 4 is an enlarged plan view of a ripple preventing unit of the driving board shown in FIG. 3;

FIG. 5a is a partial cross-sectional view taken along line Va-Va′ in FIG. 4;

FIG. 5b is a partial cross-sectional view taken along line Vb-Vb′ in FIG. 4;

FIG. 6 is a graph of noise level versus frequency illustrating a noise evaluation result according to different arrangements of multi-layer ceramic condensers in the display device shown in FIG. 1;

FIG. 7 is a partial cross-sectional view of a driving board included in an exemplary embodiment of a display device according to the present invention; and

FIG. 8 is a partial cross-sectional view taken along line VIII-VIII′ in FIG. 7.

### DETAILED DESCRIPTION OF THE INVENTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, exemplary embodiments of the present invention will be described in further detail with reference to the accompanying drawings.

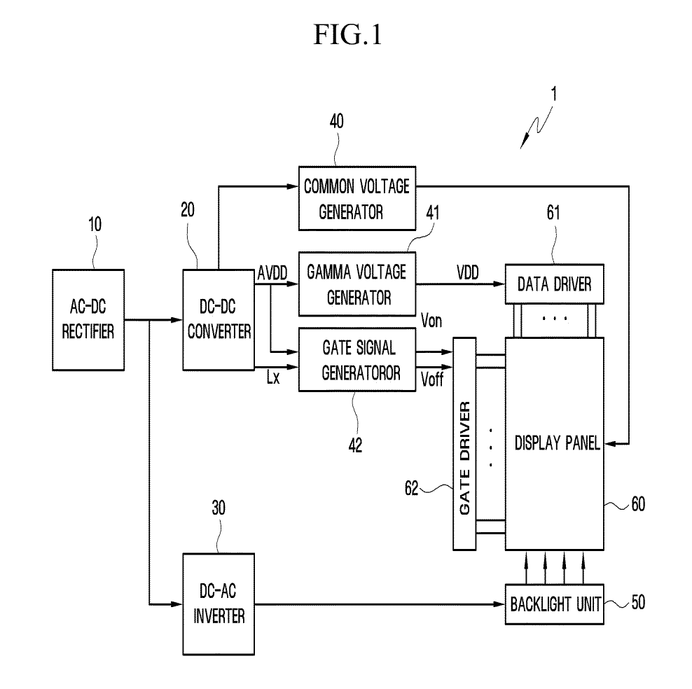

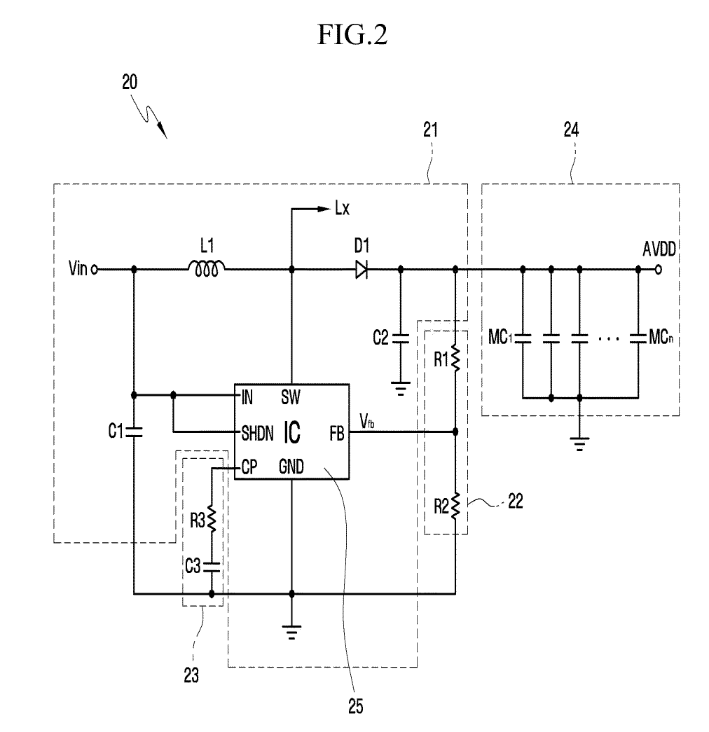

A display device according to an exemplary embodiment of the present invention will now be described in further detail with reference to FIGS. 1 and 2. FIG. 1 is a block diagram of an exemplary embodiment of a display device 1 according to the present invention, and FIG. 2 is a schematic circuit diagram of a direct current-to-direct current (“DC-DC”) converter 20 included in the display device 1 shown in FIG. 1.

The display device 1 according to an exemplary embodiment displays predetermined picture information provided from an external graphic controller (not shown) on a display panel 60. The display device 1 includes an alternating current-to-direct current (“AC-DC”) rectifier 10, a direct current-to-alternating current (“DC-AC”) inverter 30, the DC-DC converter 20 (best shown in FIG. 2), a common voltage generator 40, a gamma voltage generator 41, a gate signal generator 42, a display panel 60, a data driver 61, a gate driver 62 and a backlight unit 50.

The AC-DC rectifier 10 receives an alternating current (“AC”) power voltage having a value from about 100 volts (“V”) to about 240 V, converts the AC power voltage into a high-level direct current (“DC”) power voltage having a value from about 500 V to 600 V, and outputs a converted DC voltage to the DC-AC inverter 30 and the DC-DC converter 20. The AC-DC rectifier 10 has a power factor correction (“PFC”) function, and may be implemented by a diode rectifier or an active pulse width modulation (“PWM”) rectifier.

The DC-AC inverter 30 supplies, e.g., applies, a driving voltage to driving a lamp (not shown) in the backlight unit 50. The DC-AC inverter 30 changes the high-level DC power voltage generated from the AC-DC rectifier 10 into a voltage level suitable to drive the lamp (not shown) and outputs the changed voltage to the backlight unit 50.

In addition, the DC-AC inverter 30 changes the high-level DC power voltage generated from the AC-DC rectifier 10 into an AC power voltage suitable to be used as a backlight and outputs the changed voltage to backlight unit 50. A collector resonance type circuit, such as a “Royer inverter,” for example, or a push-pull inverter, a half-bridge inverter or a full-bridge inverter, may be used as the DC-AC inverter 30, but alternative exemplary embodiments are not limited thereto.

The DC-DC converter 20 converts the high-level DC power voltage generated from the AC-DC rectifier 10 into a pulse signal Lx and/or an analog power voltage AVDD, and transmits the pulse signal Lx and/or the analog power voltage AVDD to the common voltage generator 40, the gamma voltage generator 41 and the gate signal generator 42. The common voltage generator 40, the gamma voltage generator 41 and the gate signal generator 42 generate a common voltage Vcom, a gamma voltage VDD, a gate on signal Von and a gate off signal Voff based on the pulse signal Lx and the analog power voltage AVDD, as will now be described in further detail with reference to FIG. 2.

The DC-DC converter 20 includes a boost circuit 21, a feedback voltage generation circuit 22, a compensation circuit 23 and a ripple preventing unit 24. The boost circuit 21 includes a control chip 25, which in an exemplary embodiment is an integrated circuit (“IC”) including a power input unit IN, a control unit SHDN, a switch unit SW, a feedback unit FB and a ground unit GND. In addition, the boost circuit 21 or, alternatively, the control chip 25, further includes an inductor L1, a diode D1, an input capacitor C1, and an output capacitor C2.

When an input power voltage Vin is received through the power input unit IN, the control unit SHDN outputs a control signal for controlling operation of the DC-DC converter 20 using the received input power voltage Vin.

The switch unit SW is connected to a switching element (not shown), which is either internally or externally provided, to control operation of the boost circuit 21, thereby shifting a voltage level of the input power voltage Vin to a level of the pulse signal Lx. The switch unit SW is switched according to externally inputted switch control signals (not shown). In an exemplary embodiment, the switch unit SW may be an n-type metal-oxide-semiconductor (“NMOS”) transistor, which includes a drain terminal connected to the feedback voltage generation circuit 22, a source terminal connected to a ground terminal and a gate terminal connected to an external circuit (not shown) to receive the switch control signal inputted from the external circuit. In operation, the switch unit SW boosts the input power voltage Vin to generate the pulse signal Lx. The pulse signal Lx is converted into an analog power voltage AVDD by the diode D1 and the output capacitor C2. In an exemplary embodiment, the pulse signal Lx has a switching waveform corresponding to a source signal of the analog power voltage AVDD, e.g., an orthogonal waveform having a predetermined level. The pulse signal Lx can also be used for a charge pumping circuit (not shown) provided in the gate signal generator 42.

The feedback unit FB receives a feedback voltage Vfb supplied from the feedback voltage generation circuit 22 and transmits the feedback voltage Vfb to the switch unit SW. In an exemplary embodiment, the feedback voltage Vfb is generated by dividing the analog power voltage AVDD in the feedback voltage generation circuit 22.

As described in greater detail above, the power input unit IN, the control unit SHDN, the switch unit SW, the feedback unit FB and the ground unit GND may be included in an integrated circuit, e.g., a single chip, incorporating the above-mentioned functions of respective components therein or, alternatively, may be disposed in separate, independent circuits including separate functions of corresponding components.

In addition, the inductor L1 included in the boost circuit 21 is connected to an input voltage node, to which the input voltage Vin is applied, at an end thereof, and the inductor L1 stores the input voltage therein. The inductor L1 includes a second, opposite, end connected to the control chip 25 including the switch unit SW, among other components (as described above).

The input power voltage Vin is converted into the pulse signal Lx by the switching portion SW connected to the inductor L1, and the converted pulse signal Lx is rectified by the diode D1 and is outputted as the analog power voltage AVDD. In an exemplary embodiment, the input capacitor C1 and the output capacitor C2 are provided to stabilize the input power voltage Vin and the analog power voltage AVDD.

The feedback voltage generation circuit 22 generates the feedback voltage Vfb for generating the analog power voltage AVDD according to the externally supplied switch control signal, and outputs the feedback voltage Vfb to the feedback unit FB of the control chip 25. The feedback voltage generation circuit 22 may include a first resistor R1 and a second resistor R2, which in an exemplary embodiment are first and second partial pressure resistors R1 and R2, respectively.

The first and second partial pressure resistors R1 and R2, respectively, divide the analog power voltage AVDD according to a predetermined ratio and generate the feedback voltage Vfb. The feedback voltage generation circuit 22 according to an exemplary embodiment may further include one or more resistors for further voltage adjustment, in addition to the first and second partial pressure resistors R1 and R2, respectively. To increase stability of the analog power voltage AVDD, a number of capacitors included in an exemplary embodiment may also be increased.

The compensation circuit 23 adjusts an output variation depending on a load change of the analog power voltage AVDD, and includes a resistor R3 and a capacitor C3.

The ripple preventing unit 24 effectively prevents ripples from being generated in the analog power voltage AVDD, and includes a plurality of multi-layer ceramic condensers MC₁-MCₙ, and each multi-layer ceramic condenser MC₁-MCₙ of the plurality thereof includes a first end to which the analog power voltage AVDD is applied, and a second, opposite, end to which the ground voltage GND is applied, as will be described in further detail below.

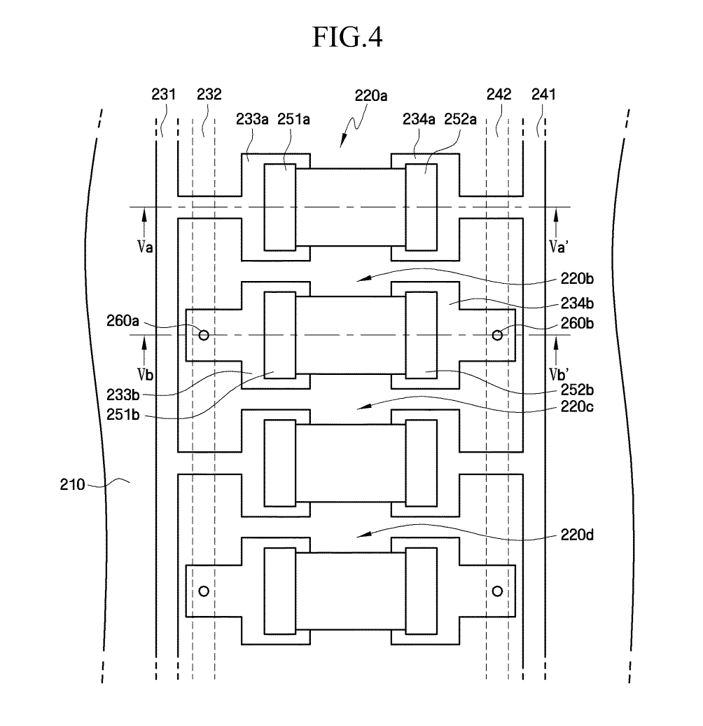

The multi-layer ceramic condensers MC₁-MCₙ of the plurality of multi-layer ceramic condensers MC₁-MCₙ are disposed adjacent to and arranged substantially in parallel to one another, as best shown in FIG. 4, which will be described in further detail below. When currents are applied to the multi-layer ceramic condensers MC₁-MCₙ, vibrations are caused due to a piezo effect. In addition, a given multi-layer ceramic condenser of the multi-layer ceramic condensers MC₁-MCₙ may resonate with an adjacent multi-layer ceramic condenser, and the vibrations are therefore amplified, producing substantial noise. Therefore, the plurality of multi-layer ceramic condensers MC₁-MCₙ in an exemplary embodiment are disposed such that currents applied to adjacent multi-layer ceramic condensers are opposite to each other, thereby substantially offsetting and/or effectively minimizing the vibrations and/or noise. Thus, in an exemplary embodiment, the multi-layer ceramic condensers MC₁-MCₙ are arranged substantially in parallel to one another and currents having opposite directions thereof are applied to adjacent multi-layer ceramic condensers, thereby effectively preventing vibration (and/or noise from being produced due to the vibration).

The multi-layer ceramic condensers MC₁-MCₙ will be described in further detail below.

Referring again to FIG. 1, the common voltage generator 40 generates a common voltage Vcom using DC power, a level of which is converted by the DC-DC converter 20, and delivers the common voltage Vcom to the display panel 60.

The gamma voltage generator 41 receives the analog power voltage AVDD from the DC-DC converter 20, generates a gamma voltage VDD, and delivers the gamma voltage VDD to the data driver 61.

The data driver 61 performs gamma correction on a picture signal for display using the gamma voltage VDD delivered from the gamma voltage generator 41, and outputs the gamma-corrected picture signal to the display panel 60.

The gate signal generator 42 receives the analog power voltage AVDD and the pulse signal Lx from the DC-DC converter 20, and generates the gate on signal Von, and the gate off signal Voff for gate operation.

The gate driver 62 applies the gate on signal Von and/or the gate off signal Voff to a gate line of the display panel 600 to drive a switching element (not shown) connected to the gate line.

The display panel 60 receives electrical signals from the data driver 61 and the gate driver 62 and displays an image on a screen (not shown) of the display panel 60. The display panel 600 includes two substrates, e.g., a common electrode substrate and a thin film transistor (“TFT”) substrate (neither shown), disposed opposite to each other, e.g., facing each other, with a predetermined distance provided therebetween. The display panel 60 also includes a liquid crystal layer (not shown) including liquid crystal molecules oriented in a predetermined direction in a space between the two substrates.

In addition, the display panel 60 is connected to the data driver 61 and the gate driver 62 through data and gate lines, respectively, and the backlight unit 50 is disposed below the display panel 60 as a light source for providing light to the display panel 60.

The backlight unit 50, included as a light source for the display panel 60 (which does not emit light by itself) irradiates light from a rear portion of the display panel 60. The backlight unit 50 according to an exemplary embodiment includes fluorescent lamps (not shown), which may be arranged in various configurations, including a direct type configuration or an edge type configuration, for example, according to a desired configuration of the display device 1.

The fluorescent lamps receive the high-level DC voltage supplied from, e.g., applied from, the DC-AC inverter 30 and thereby emit light.

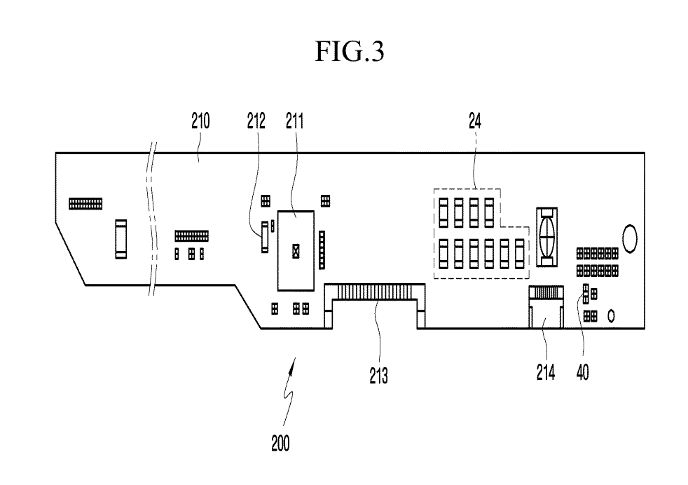

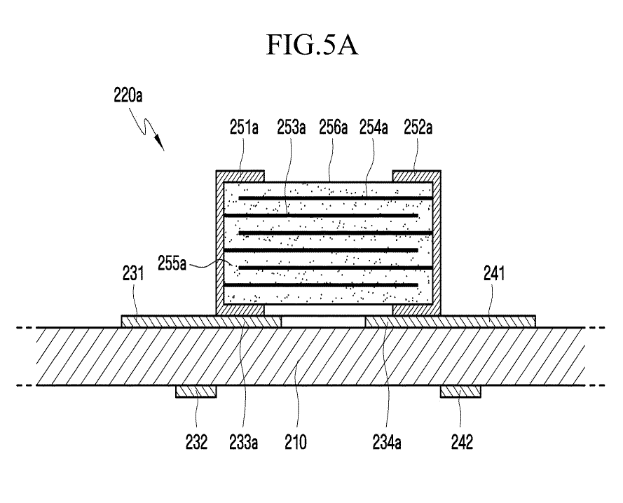

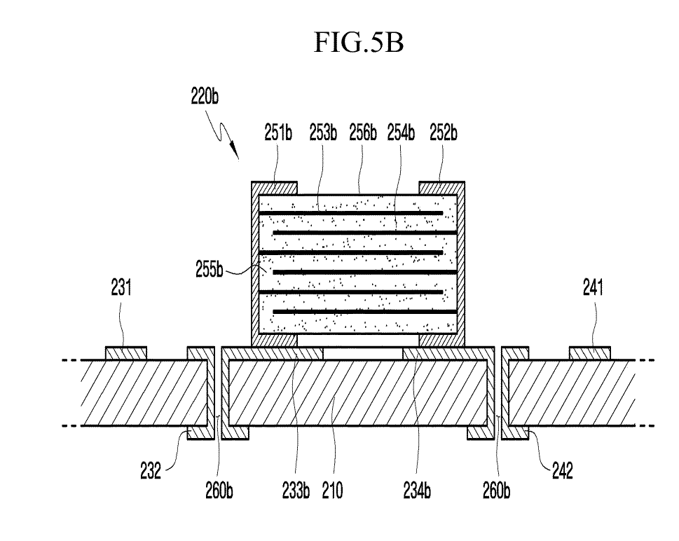

Hereinafter, a driving board included in the display device shown in FIG. 1 will be described in further detail with reference to FIGS. 3 through 5. FIG. 3 is a plan view of a driving board included in the display device shown in FIG. 1, FIG. 4 is an enlarged plan view of a ripple preventing unit of the driving board shown in FIG. 3, FIG. 5a is a partial cross-sectional view taken along line Va-Va′ in FIG. 4, and FIG. 5b is a partial cross-sectional view taken along line Vb-Vb′ in FIG. 4.

Referring to FIGS. 3 and 4, a driving board 200 included in the display device 1 according to an exemplary embodiment includes a timing controller 211, a memory chip 212, a ripple preventing unit 24, an input power connector 213, a test signal connector 214 and a common voltage generator 40. The driving board 200 may include a single layered structure with two-sided wiring patterns or, alternatively, a multi-layered structure including different boards for mounting various parts and/or printing wirings thereon.

The timing controller 211 receives an image signal and an input control signal for controlling the image signal from an external graphic controller (not shown), generates a gate control signal and a data control signal, and transmits the gate control signal and the data control signal, as well as the image signal, to the gate driver 62 (FIG. 1), and the data driver 61 (FIG. 1).

The memory chip 212 stores data for operating the timing controller 211. For example, various conditions for generating the data control signal and the gate control signal may be stored in the memory chip 212. In an exemplary embodiment, the memory chip 212 may be an electrically erasable and programmable read only memory (“EEPROM”), but alternative exemplary embodiments are not limited thereto.

The input power connector 213, to which input power is applied, the test signal connector 214, to which a test signal is applied, and other component parts for driving the display panel 60, are disposed on, e.g., are mounted on, the driving board 200.

The ripple preventing unit 24 includes a plurality of multi-layer ceramic condensers 220a, 220b, 220c and 220d arranged substantially in parallel to one another, as shown in FIG. 4. Multi-layer ceramic condensers 220a, 220b, 220c and 220d of the plurality of multi-layer ceramic condensers 220a, 220b, 220c and 220d are disposed adjacent to one another. As a result, the multi-layer ceramic condensers 220a, 220b, 220c and 220d may resonate with one another due to vibrations occurring from adjacent multi-layer ceramic condensers 220a, 220b, 220c and 220d. To effectively prevent the multi-layer ceramic condensers 220a, 220b, 220c and 220d from resonating, in an exemplary embodiment, currents are applied to adjacent multi-layer ceramic condensers in different directions. In an exemplary embodiment, the currents applied are opposite to each other, e.g., flow in opposite directions through adjacent multi-layer ceramic condensers.

Since the multi-layer ceramic condensers 220a, 220b, 220c, and 220d in an exemplary embodiment are not substantially affected with respect to a direction of current therethrough, they are arranged substantially in parallel to one another and a same current is alternately applied to adjacent multi-layer ceramic condensers of the multi-layer ceramic condensers 220a, 220b, 220c and 220d, as will be described in further detail below.

The ripple preventing unit 24 according to an exemplary embodiment will now be described in further detail with reference to FIGS. 4 through 5b.

As described above, the ripple preventing unit 24 according to an exemplary embodiment includes the plurality of multi-layer ceramic condensers 220a, 220b, 220c, and 220d. In addition, the multi-layer ceramic condensers 220a, 220b, 220c, and 220d are arranged such that a first multi-layer ceramic condenser 220a and a second multi-layer ceramic condenser 220b are adjacent to each other and are repeatedly arranged in an alternating pattern. For example, the first multi-layer ceramic condenser 220a and the second multi-layer ceramic condenser 220b are alternately and repeatedly arranged. Thus, the first multi-layer ceramic condenser 220a is substantially the same as a third multi-layer ceramic condenser 220c, while the second multi-layer ceramic condenser 220b is substantially the same as a fourth multi-layer ceramic condenser 220d. For purposes of explanation herein, the following more detailed description will be made with reference to an arrangement of the first multi-layer ceramic condenser 220a and the second multi-layer ceramic condenser 220b, but it will be noted that exemplary embodiments include any structure which includes two or more multi-layer ceramic condensers, sequentially and alternately disposed in parallel to one another on the ripple preventing circuit 24.

Referring now to FIGS. 4 and 5, a first upper wiring 231 and a second upper wiring 241 are disposed on a first surface of a substrate 210. In an exemplary embodiment, for example, the first upper wiring 231 and the second upper wiring 241 are disposed on the first surface, which is an upper surface, e.g., a top surface, of the substrate 210, as shown in FIG. 5a. In an exemplary embodiment different voltages are be applied to the first upper wiring 231 and the second upper wiring 241, as will be described in further detail below.

In addition, a first lower wiring 242 and a second lower wiring 232 are disposed on a second surface, e.g., a lower surface, opposite the first surface, of the substrate 210. In an exemplary embodiment, for example, the first lower wiring 242 and the second lower wiring 232 are disposed on the lower surface, e.g., a bottom surface, of the substrate 210, and different voltages are be applied to the first lower wiring 242 and the second lower wiring 232. In exemplary embodiments, the abovementioned surfaces on which the first lower wiring 242 and the second lower wiring 232 are not limited to the bottom surface of the substrate 210. For example, in an exemplary embodiment in which the substrate 210 includes a multi-layered structure including various layers (not shown), the first lower wiring 242 and the second lower wiring 232 may be disposed on a surface different from that where the first upper wiring 231 and the second upper wiring 241 are disposed in the exemplary embodiment shown in FIG. 5.

Pads 233a and 234a extend from the first upper wiring 231 and the second upper wiring 241, respectively, to allow the first multi-layer ceramic condenser 220a to be mounted, e.g., disposed and/or connected, thereon. To allow the first and second electrodes 251a and 252a, respectively, of the first multi-layer ceramic condenser 220a to contact each other, the pads 233a and 234a extend from the first upper wiring 231 and the second upper wiring 241, respectively, and are spaced apart from each other.

In addition, pads 233b and 234b are disposed at a location where the second multi-layer ceramic condenser 220b is mounted. The pads 233b and 234b are disposed at locations corresponding to the first and second electrodes 251b and 252b, respectively, of the second multi-layer ceramic condenser 220b. The pads 233b and 234b are connected to the second lower wiring 232 and the first lower wiring 242, respectively, using vias 260a and 260b, respectively.

In an exemplary embodiment, a same first voltage is applied to both the first upper wiring 231 and the first lower wiring 242, which will hereinafter be collectively referred to as “first wirings (231, 242)”, and a same second voltage, different from the first voltage, is applied to both the second upper wiring 241 and the second lower wiring 232, which will hereinafter be collectively referred to as “second wirings (241, 232)”.

The first upper wiring 231 is connected to the first electrode 251a of the first multi-layer ceramic condenser 220a, and the first lower wiring 242 is connected to the second electrode 252b of the second multi-layer ceramic condenser 220b. The first upper wiring 231 and the second lower wiring 232 are disposed at ends of the first multi-layer ceramic condenser 220a and the second multi-layer ceramic condenser 220b.

In addition, the second upper wiring 241 is connected to the second electrode 252a of the first multi-layer ceramic condenser 220a, and the second lower wiring 232 is connected to the first electrode 251b of the second multi-layer ceramic condenser 220b. The second upper wiring 241 is disposed proximate to the first lower wiring 242, and the second lower wiring 232 is disposed proximate to the first upper wiring 231.

When different voltages are applied to the first wirings 231 and 242 and the second wirings 241 and 232, currents flow in the first multi-layer ceramic condenser 220a and the second multi-layer ceramic condenser 220b in opposite directions. Accordingly, noise generated due to vibrations of the first multi-layer ceramic condenser 220a and the second multi-layer ceramic condenser 220b is substantially reduced and/or is effectively prevented by applying first and second currents to the first and multi-layer ceramic condensers 220a and 220b, respectively, such that the first and second currents to flow in opposite directions.

More particularly, to apply the first and second currents to the first and second multi-layer ceramic condensers 220a and 220b, respectively, the first voltage, which in an exemplary embodiment is an analog power voltage, may be applied to the first wirings 231 and 242, and the second voltage, which is a ground voltage in an exemplary embodiment, may be applied to the second wirings 241 and 232.

A vibration preventing structure of the first multi-layer ceramic condenser 220a and the second multi-layer ceramic condenser 220b will now be described in further detail with reference to FIGS. 5a and 5b.

Multi-layer ceramic condensers having substantially the same configurations as those of the first multi-layer ceramic condenser 220a and the second multi-layer ceramic condenser 220b may be used. The first multi-layer ceramic condenser 220a includes the first electrode 251a, the second electrode 252a, a first internal electrode 253a, a second internal electrode 254a, a dielectric material 255a and a housing 256a. The second multi-layer ceramic condenser 220b includes the first electrode 251b, the second electrode 252b, a first internal electrode 253b, a second internal electrode 254b, a dielectric material 255b and a housing 256b.

One or more of the first internal electrodes 253a and 253b connected to the first electrodes 251a and 251b are disposed within the housings 256a and 256b, and the second internal electrodes 254a and 254b connected to the second electrode 252a and 252b are disposed between the first internal electrodes 253a and 253b. The first internal electrodes 253a and 253b and the second internal electrodes 254a and 254b include a substantially rectilinear shape, e.g., a thin plate shape, and are insulated by the dielectric materials 255a and 255b within the housings 256a and 256b, respectively.

In the first multi-layer ceramic condenser 220a and the second multi-layer ceramic condenser 220b, when the first voltage and the second voltage, respectively, are applied to the first electrodes 251a and 251b and the second electrode 252a and 252b, respectively, vibrations are produced at the first internal electrodes 253a and 253b and the second internal electrodes 254a and 254b by a piezo effect.

The vibrations produced in the first multi-layer ceramic condenser 220a and the second multi-layer ceramic condenser 220b may cause a vibration to the substrate 210. Moreover, when vibrations having a same frequency are combined, constructive interference causes an increased amplitude of vibration to be produced. Thus if the same level of voltage were applied to the first multi-layer ceramic condenser 220a and the second multi-layer ceramic condenser 220b in the same direction, the vibrations produced at the first multi-layer ceramic condenser 220a and the second multi-layer ceramic condenser 220b would add up (due to the constructive interference), thereby producing noises.

In addition, if the vibrating frequencies of the first multi-layer ceramic condenser 220a and the second multi-layer ceramic condenser 220b are substantially the same as natural resonant frequencies of the substrate 210, the substrate 210, the first multi-layer ceramic condensers 220a and 220b, and the second multi-layer ceramic condensers 220a and 220b will resonate with one another, and additional noises, as well as increased vibrations, are thereby produced.

However, in an exemplary embodiment, even when the first multi-layer ceramic condenser 220a and the second multi-layer ceramic condenser 220b are adjacent to one another and are arranged substantially in parallel, vibrations produced at the first multi-layer ceramic condenser 220a and the second multi-layer ceramic condenser 220b are offset by the currents applied thereto, which flow in opposite directions therein. Thus, in an exemplary embodiment, noise is effectively prevented from being generated from the first multi-layer ceramic condenser 220a and the second multi-layer ceramic condenser 220b.

As described herein, multi-layer ceramic condensers included in a ripple preventing unit are described as an exemplary embodiment for convenience of description. However, alternative exemplary embodiments are not limited thereto. Rather, alternative exemplary embodiments can also be applied to any circuit constructed to have a substrate on which a plurality of multi-layer ceramic condensers may be mounted. An exemplary embodiments can also be applied to a capacitor C1 connected to the input unit IN (FIG. 2) and/or a charge pump circuit (not shown) for generating the gate on signal Von.

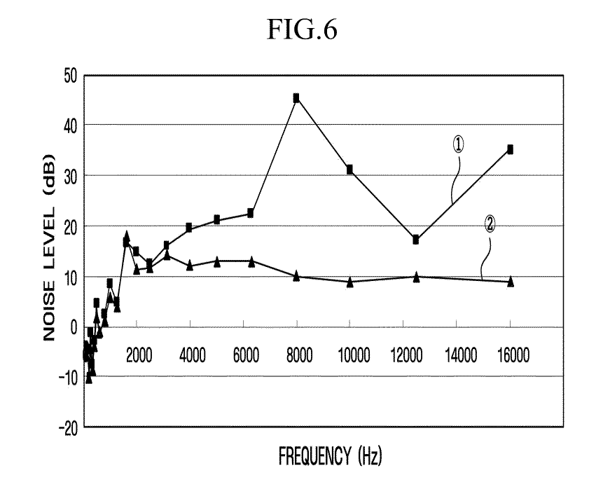

FIG. 6 is graph of noise level, in decibels (dB) versus frequency, in Hertz (Hz), illustrating noise evaluation results based arrangements of multi-layer ceramic condensers in the display device shown in FIG. 1.

In FIG. 6, a first dot plot \textcircled{1} illustrates frequency dependency of noise measured when multi-layer ceramic condensers are arranged adjacent and substantially in parallel to each other and currents are applied thereto in a same direction. In contrast, dot plot \textcircled{2} illustrates the frequency dependency of noise measured in an exemplary embodiment in which multi-layer ceramic condensers are arranged adjacent and substantially in parallel to each other and currents having opposite directions are applied to adjacent multi-layer ceramic condensers.

As shown in FIG. 6, noise levels represented in the dot plot \textcircled{2} are substantially lower than those represented by the dot plot \textcircled{1}. More particularly, at about 2000 Hz or higher, a noise preventing effect is substantially increased in the exemplary embodiment in which the multi-layer ceramic condensers are connected in parallel, and currents are applied to adjacent multi-layer ceramic condensers in opposite directions.

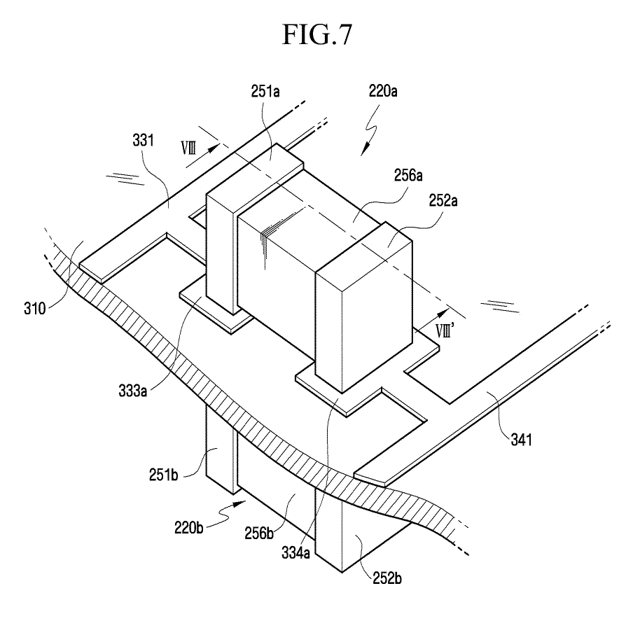

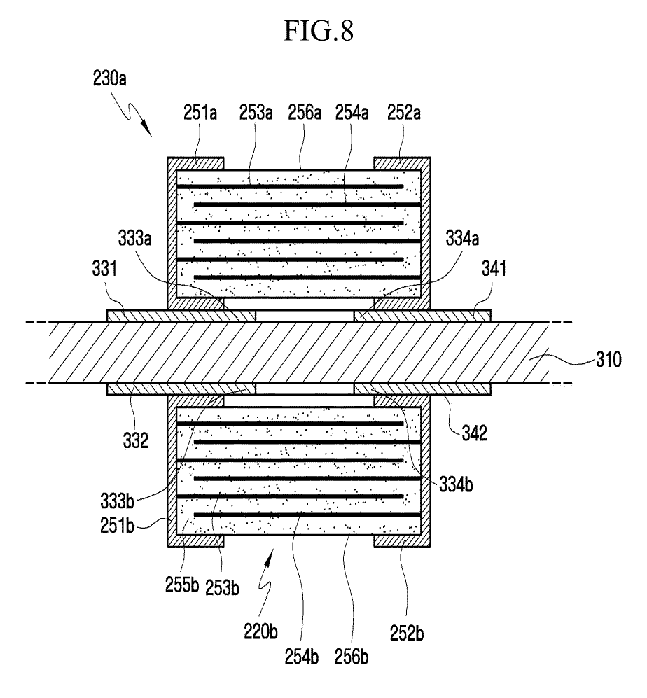

Hereinafter, a display device according to an exemplary embodiment will be described in further detail with reference to FIGS. 7 and 8. FIG. 7 is a partial cross-sectional view of a driving board included in an exemplary embodiment of a display device according to the present invention, and FIG. 8 is a partial cross-sectional view taken along line VIII-VIII′ in FIG. 7. For convenience of description, components having the same or like function as described in greater detail above are identified by the same reference characters, and any repetitive detailed description thereof will hereinafter be omitted.

In an exemplary embodiment, a first upper wiring 331 and a second upper wiring 341 are disposed on a first surface, e.g., an upper surface, of a substrate 310. In an exemplary embodiment, the first upper wiring 331 and the second upper wiring 341 are disposed on the upper surface, e.g., a top surface, of the substrate 210, and different voltages are applied to the first upper wiring 331 and the second upper wiring 341.

In addition, a first lower wiring 342 and a second lower wiring 332 are disposed on a second surface, e.g., a lower surface, opposite the first surface, of the substrate 310. In an exemplary embodiment, the first upper wiring 342 and the second lower wiring 332 are disposed on the lower surface, e.g., a bottom surface, of the substrate 310, and different voltages are applied to the first upper wiring 342 and the second lower wiring 332.

In the display device according to an exemplary embodiment, a first multi-layer ceramic condenser 220a and a second multi-layer ceramic condenser 220b are disposed on the first surface and the second surface, respectively, of the substrate 310, and currents flowing in different, e.g. opposite, directions are supplied to the first multi-layer ceramic condenser 220a and the second multi-layer ceramic condenser 220b. In an exemplary embodiment, the first multi-layer ceramic condenser 220a and the second multi-layer ceramic condenser 220b are disposed directly opposite to and facing each other with the substrate 310 disposed therebetween, as shown in FIG. 8.

Pads 333a and 334a extend from the first upper wiring 331 and the second upper wiring 341 to allow the first multi-layer ceramic condenser 220a to be mounted thereon. In order to allow the first and second electrodes 251a and 252a, respectively, of the first multi-layer ceramic condenser 220a to contact each other, the pads 333a and 334a extend from the first upper wiring 331 and the second upper wiring 341, respectively, and are spaced apart from each other, as shown in FIG. 8.

Likewise, pads 333b and 334b (FIG. 8) extend from the second lower wiring 332 and the first lower wiring 342, respectively, to allow the second multi-layer ceramic condenser 220b to be mounted thereon, and are disposed on the second surface of the substrate 310. The pads 333b and 334b disposed on the second surface of the substrate 310 may be disposed at locations substantially corresponding to the pads 333a and 334a, respectively, which are disposed on the first surface of the substrate 310 on which the first multi-layer ceramic condenser 220a is disposed.

As described in greater detail above, the first multi-layer ceramic condenser 220a and the second multi-layer ceramic condenser 220b are disposed on opposite respective surfaces of the substrate 310.

In an exemplary embodiment, a same first voltage is supplied to the first upper wiring 331 and the first lower wiring 342, which will hereinafter be collectively referred to as “first wirings (331, 342)”, and a same second voltage, different than the first voltage, is supplied to the second upper wiring 341 and the second lower wiring 332, which will hereinafter collectively be referred to as “second wirings (341, 332)”.

The first upper wiring 331 is connected to the first electrode 251a of the first multi-layer ceramic condenser 220a, and the first lower wiring 342 is connected to the second electrode 252b of the second multi-layer ceramic condenser 220b.

Likewise, the second upper wiring 341 is connected to the second electrode 252a of the first multi-layer ceramic condenser 220a, and the second lower wiring 332 is connected to the first electrode 255b of the second multi-layer ceramic condenser 220b.

When different voltages, e.g., the first voltage and the second voltage, are applied to the first wirings 331 and 342 and the second wirings 341 and 332, respectively, a first current and a second current, respectively, flow in opposite directions in the first multi-layer ceramic condenser 220a and the second multi-layer ceramic condenser 220b. Thus, noise due to vibrations of the first multi-layer ceramic condenser 220a and the second multi-layer ceramic condenser 220b are substantially reduced and/or effectively prevented in an exemplary embodiment in which the first current and the second current, flowing in opposite directions, are supplied to the first multi-layer ceramic condenser 220a and the second multi-layer ceramic condenser 220b, respectively, thereby causing the first current and the second currents to flow in opposite directions therethrough.

Thus, in an exemplary embodiment, the first multi-layer ceramic condenser 220a and the second multi-layer ceramic condenser 220b are disposed symmetrically on opposite surfaces of the substrate 310 and different currents are applied to the first multi-layer ceramic condenser 220a and the second multi-layer ceramic condenser 220b and flow therethrough in opposite directions, thereby effectively preventing the first multi-layer ceramic condenser 220a and the second multi-layer ceramic condenser 220b from resonating with the substrate 310. Accordingly noise is substantially reduced and/or is effectively minimized in a display device according to an exemplary embodiment.

The exemplary embodiments described herein will be considered in all respects as illustrative and not restrictive, reference being made to the appended claims rather than the foregoing description to indicate the scope of the invention. Moreover, while the present invention has been particularly shown and described with reference to exemplary embodiments thereof, it will be understood by those of ordinary skill in the art that various changes in form and details may be made therein without departing from the spirit or scope of the present invention as defined by the following claims.

What is claimed is:

1. A display device comprising:
a display panel on which an image is displayed; and
a driving board which applies a driving signal to the display panel, the driving board comprising:
a substrate;
a first multi-layer ceramic condenser disposed on the substrate; and
a second multi-layer ceramic condenser disposed substantially parallel to the first multi-layer ceramic condenser on the substrate, wherein
a first current is applied to the first multi-layer ceramic condenser,
a second current is applied to the first multi-layer ceramic condenser, and
a direction of the first current is opposite to a direction of the second current.

2. The display device of claim 1, wherein the first multi-layer ceramic condenser and the second multi-layer ceramic condenser are mounted on a same surface of the substrate.

3. The display device of claim 2, further comprising a plurality of first multi-layer ceramic condensers and a plurality of second multi-layer ceramic condenser wherein first multi-layer ceramic condensers of the plurality of first multi-layer ceramic condensers and second multi-layer ceramic condensers of the plurality of second multi-layer ceramic condensers are sequentially and alternately arranged on the substrate.

4. The display device of claim 1, wherein
the first multi-layer ceramic condenser is mounted on a first surface of the substrate, and
the second multi-layer ceramic condenser is mounted on a second surface, opposite the first surface, of the substrate.

5. The display device of claim 4, wherein the first multi-layer ceramic condenser and the second multi-layer ceramic condenser face each other and are disposed opposite to each other with the substrate disposed therebetween.

6. The display device of claim 1, further comprising:
a first wiring disposed on the substrate; and
a second wiring disposed on the substrate, spaced apart from the first wiring, wherein
the first multi-layer ceramic condenser and the second multi-layer ceramic condenser each include a first electrode and a second electrode,
the first wiring applies a first voltage to the first electrode of the first multi-layer ceramic condenser and the second electrode of the second multi-layer ceramic condenser, and
the second wiring applies a second voltage to the second electrode of the first multi-layer ceramic condenser and the first electrode of the second multi-layer ceramic condenser.

7. The display device of claim 6, wherein
the first wiring includes a first upper wiring disposed on the first surface of the substrate and a first lower wiring disposed on the second surface of the substrate, and
the second wiring includes a second upper wiring disposed on the first surface of the substrate and a second lower wiring disposed on the second surface of the substrate.

8. The display device of claim 7, wherein the first multi-layer ceramic condenser and the second multi-layer ceramic condenser are connected to each other through a via and one of the first lower wiring and the second lower wiring.

9. The display device of claim 6, further comprising a boost circuit disposed on the substrate and which boosts an input voltage to generate an analog power voltage.

10. The display device of claim 9, wherein the first voltage is the analog power voltage.

11. The display device of claim 9, wherein the second voltage is a ground voltage.

12. The display device of claim 9, wherein
the boost circuit includes a control chip and an inductor disposed between the control chip and an input voltage node to which the input voltage is applied, and
the control chip receives a feedback voltage and controls an amount of current flowing from the input voltage node to the inductor.

13. A method of driving a display device, the method comprising:
applying a first current to a first multi-layer ceramic condenser and a second current to a second multi-layer ceramic condenser arranged substantially parallel to the first multi-layer ceramic condenser on a substrate to output a driving signal; and
displaying an image on a display panel using the driving signal,
wherein a direction of the first current applied to the first multi-layer ceramic condenser is opposite to a direction of the second current applied to the second multi-layer ceramic condenser.

14. The method of claim 13, wherein the first multi-layer ceramic condenser and the second multi-layer ceramic condenser are disposed on a same surface of the substrate.

15. The method of claim 13, wherein
the first multi-layer ceramic condenser is disposed on a first surface of the substrate, and
the second multi-layer ceramic condenser is disposed on a second surface, opposite the first surface, of the substrate.

16. The method of claim 13, wherein the display device comprises a first wiring disposed on the substrate and a second wiring spaced apart from the first wiring on the substrate, and the first multi-layer ceramic condenser and the second multi-layer ceramic condenser each include a first electrode and a second electrode, the method further comprising:
applying a first voltage to the first electrode of the first multi-layer ceramic condenser and the second electrode of the second multi-layer ceramic condenser; and
applying a second voltage to the second electrode of the first multi-layer ceramic condenser and the first electrode of the second multi-layer ceramic condenser.

17. The method of claim 16, wherein
the first wiring includes a first upper wiring disposed on the first surface of the substrate and a first lower wiring disposed on the second surface of the substrate, and
the second wiring includes a second upper wiring disposed on the first surface of the substrate and a second lower wiring disposed on the second surface of the substrate.

18. The method of claim 16, wherein
the display device further comprises a boost circuit disposed on the substrate, and
the method further comprises boosting an input voltage with the boost circuit to generate an analog power voltage.

19. The method of claim 18, wherein the first voltage is the analog power voltage, and the second voltage is a ground voltage.

20. The method of claim 18, wherein the boost circuit includes a control chip and an inductor disposed between the control chip and an input voltage node to which the input voltage is applied, and the method further comprises
receiving a feedback voltage with the control chip; and
controlling an amount of current flowing from the input voltage node to the inductor.
